(19) United States
(12) Patent Application Publication
(10) Pub. No.: US 2025/0297353 A1
(43) Pub. Date: Sep. 25, 2025

(54) DEPOSITION MASK

(71) Applicant: Samsung Display Co., LTD., Yongin-si (KR)

(72) Inventors: Jeong Kuk KIM, Yongin-si (KR); Yeon Woo LEE, Yongin-si (KR); Ji Hyun JUNG, Yongin-si (KR); Sung Won CHO, Yongin-si (KR); Jun Ho JO, Yongin-si (KR)

(21) Appl. No.: 18/936,568

(22) Filed: Nov. 4, 2024

(30) Foreign Application Priority Data
Mar. 19, 2024 (KR) 10-2024-0037522

(51) Int. Cl. C23C 14/04; H10K 71/16

(52) U.S. Cl. CPC C23C 14/042; H10K 71/166

(57) ABSTRACT

A deposition mask includes a mask substrate including a center area and an edge area; a plurality of cell patterns disposed on the mask substrate and including cell patterns disposed in the edge area and cell patterns disposed in the center area; and a mask frame disposed on the mask substrate and surrounding the plurality of cell patterns, where a number of cell patterns, among the cell patterns disposed in the edge area, per unit area of the edge area, among the cell patterns disposed in the center area, is greater than a number of cell patterns per unit area of the center area.

This application claims priority to Korean Patent Application No. 10-2024-0037522, filed on Mar. 19, 2024, and all the benefits accruing therefrom under 35 U.S.C. § 119, the content of which in its entirety is herein incorporated by reference.

### BACKGROUND

### 1. Field

The disclosure relates to a deposition mask.

### 2. Description of the Related Art

A wearable device is being developed which is in the form of glasses or a helmet and forms a focus at a location close to the user's eyes. For example, a wearable device may be a head mounted display (“HMD”) device or an augmented reality (“AR”) glass. Such a wearable device provides a user with an AR screen or a virtual reality (“VR”) screen.

Display specifications of at least 2,000 pixels per inch (PPI) are desired in a wearable device such as an HMD device and AR glasses to allow users to use it for a long time without dizziness. To this end, organic light-emitting diode on silicon (“OLEDoS”) technology, which is technology for a high-resolution small organic light-emitting element display device, is emerging. The OLEDOS is a technology for disposing organic light-emitting diodes (“OLEDs”) on a semiconductor wafer substrate on which a complementary metal oxide semiconductor (“CMOS”) is disposed.

### SUMMARY

Features of the disclosure provide a silicon deposition mask that may fabricate a high-resolution display panel.

Features of the disclosure provide a deposition mask that improves the adhesion between a high-resolution display panel and a deposition mask by solving the issue of warpage of a mask inorganic layer included in a mask frame.

It should be noted that features of the disclosure are not limited to the above-mentioned feature; and other features of the disclosure will be apparent to those skilled in the art from the following descriptions.

The details of embodiments of the subject matter described in this specification are set forth in the accompanying drawings and the description below.

In an embodiment of the disclosure, a deposition mask includes a mask substrate including a center area and an edge area; a plurality of cell patterns disposed on the mask substrate and including cell patterns disposed in the edge area and cell patterns disposed in the center area; and a mask frame disposed on the mask substrate and surrounding the plurality of cell patterns, where a number of cell patterns, among the cell patterns disposed in the edge area, per unit area of the edge area is greater than a number of cell patterns, among the cell patterns disposed in the center area, per unit area of the center area.

In an embodiment, the cell patterns on the edge area may be spaced apart from one another by a first distance, and the cell patterns on the center area are spaced apart from one another by a second distance, where the first distance is different from the second distance.

In an embodiment, the second distance may be greater than the first distance.

In an embodiment, the mask substrate may further include a middle area disposed between the edge area and the center area, where cell patterns on the middle area are spaced apart from one another by a third distance, and the first distance, the second distance and the third distance are different from one another.

In an embodiment, the third distance may be smaller than the second distance.

In an embodiment, the third distance may be greater than the first distance.

In an embodiment, the first distance may be equal to the third distance.

In an embodiment, the center area may include a center point of the mask substrate, and where the edge area includes an edge of the mask substrate.

In an embodiment, the center area may be in a shape of a circle having a first radius from the center point of the mask substrate, and the first radius has a range of 10% to 40% relative to a radius of the mask substrate.

In an embodiment, the mask substrate may include silicon, and the mask substrate has a circular shape in a plan view.

In an embodiment, the cell patterns may be arranged by random distances on the mask substrate.

In an embodiment, the mask frame may include a mask inorganic layer disposed on the mask substrate, and the mask inorganic layer may include an inorganic insulating material.

In an embodiment, a pixel opening may be defined in a cell pattern of the plurality of cell patterns, and the cell pattern may include a mask shadow surrounding the pixel opening.

In an embodiment, the mask shadow may include a same material as that of the mask inorganic layer.

In an embodiment, the pixel opening may be a through hole, and an ultra-high resolution pixel may be formed through the pixel opening.

In an embodiment, the mask shadow may entirely surround the pixel opening in a plan view, and the mask frame may surround an entirety of the mask shadow in the plan view.

In an embodiment of the disclosure, a deposition mask includes a mask substrate including a center area, an edge area and a middle area disposed between the center area and the edge area; a plurality of cell patterns disposed on the mask substrate; and a mask frame disposed on the mask substrate and surrounding the plurality of cell patterns, where the plurality of cell patterns does not overlap with the center area, and the plurality of cell patterns is disposed on the edge area and the middle area.

In an embodiment, the cell patterns on the edge area may be spaced apart from one another by a first distance, and the cell patterns on the middle area are spaced apart from one another by a second distance, where the first distance is different from the second distance.

In an embodiment, the cell patterns disposed on the edge area and the middle area may be all spaced apart from one another by a first distance.

In an embodiment, the cell patterns may be spaced apart from one another by random distances.

In an embodiment of the disclosure, cell patterns are arranged more in an edge area of a mask substrate of a deposition mask than in a center area of the mask substrate, thereby preventing warpage of a mask inorganic layer included in a mask frame. Accordingly, the deposition mask in an embodiment of the disclosure may enhance the adhesion between the high-resolution display panel and the deposition mask.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view showing an embodiment of a head-mounted electronic device according to the disclosure.

FIG. 2 is an exploded perspective view showing an embodiment of the head-mounted electronic device of FIG. 1.

FIG. 3 is a perspective view showing an embodiment of a head-mounted electronic device according to the disclosure.

FIG. 4 is an exploded, perspective view showing an embodiment of a display device according to the disclosure.

FIG. 5 is a cross-sectional view showing an embodiment of a part of a display panel according to the disclosure.

FIG. 6 is a plan view of an embodiment of a mask according to the disclosure.

FIG. 7 is an enlarged plan view of area A of FIG. 6.

FIG. 8 is a cross-sectional view taken along line X1-X1′ of FIG. 7.

FIG. 9 is a plan view showing an embodiment of a layout of areas included in a mask substrate according to the disclosure.

FIG. 10 is a plan view showing a plurality of cell patterns arranged on the mask substrate of FIG. 9.

FIGS. 11 to 13 are plan views showing a plurality of cell patterns disposed on the mask substrate of FIG. 9 according to different embodiments.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, e.g., from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the disclosure will be described in detail with reference to the accompanying drawings.

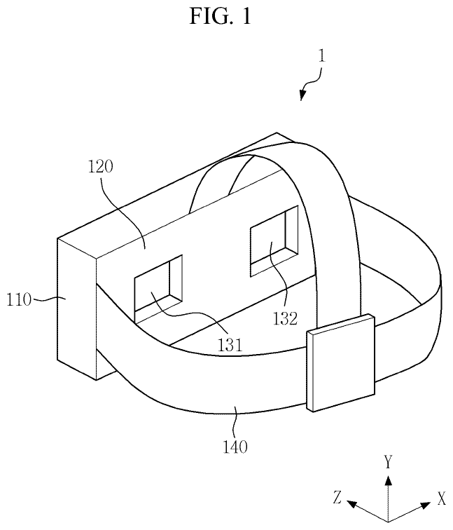

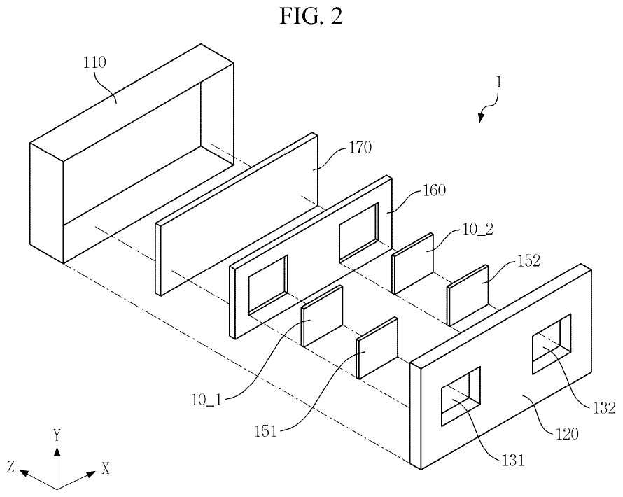

FIG. 1 is a perspective view showing an embodiment of a head-mounted electronic device according to the disclosure. FIG. 2 is an exploded perspective view showing an embodiment of the head-mounted electronic device of FIG. 1.

Referring to FIGS. 1 and 2, the head-mounted electronic device 1 in an embodiment includes a display device housing 110, a housing cover 120, a first eyepiece 131, a second eyepiece 132, a head strap band 140, a first display device 10_1, a second display device 10_2, a middle frame 160, a first optical member 151, a second optical member 152, a control circuit board 170, and a connector.

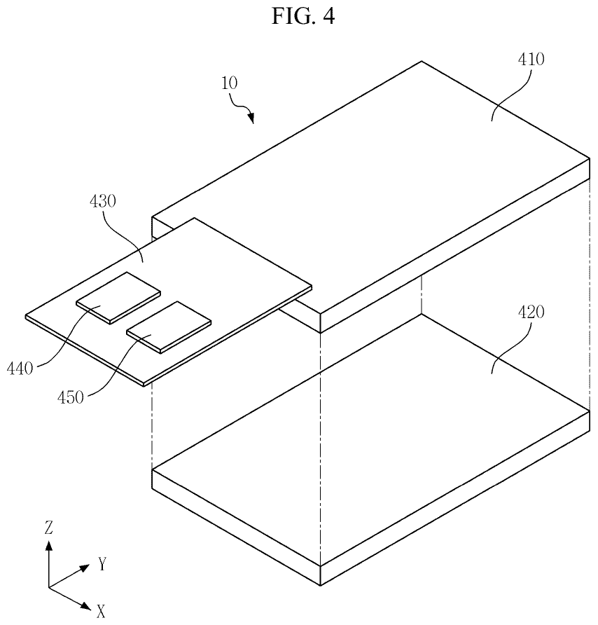

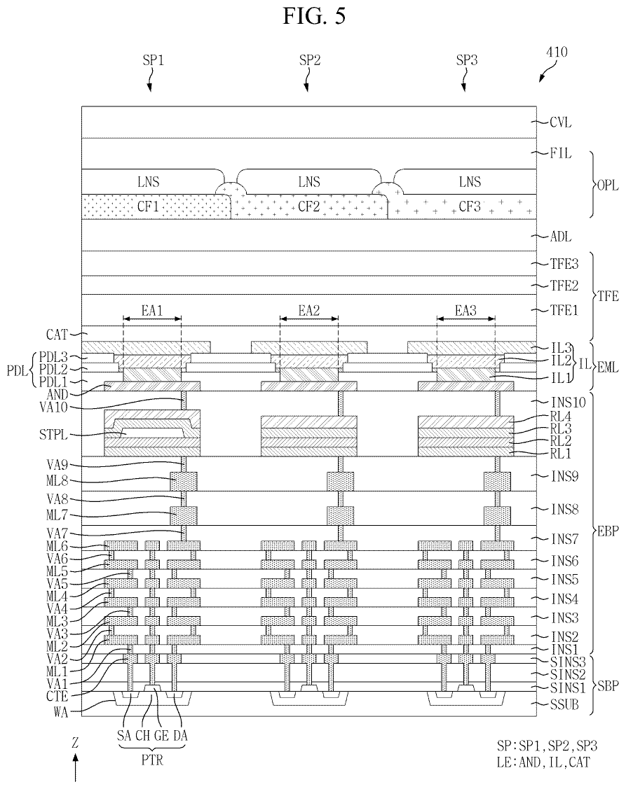

The first display device 10_1 provides images to a user's left eye, and the second display device 10_2 provides images to the user's right eye. Each of the first display device 10_1 and the second display device 10_2 is substantially identical to the display device 10 described with reference to FIGS. 4 and 5. Therefore, descriptions of the first display device 10_1 and the second display device 10_2 will be replaced with descriptions referring to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data and may transmit the digital video data to the first display device 10_1 and the second display device 10_2 through the connector.

The control circuit board 170 may transmit digital video data associated with a left eye image optimized for the user's left eye to the first display device 10_1, and may transmit digital video data associated with a right eye image optimized for the user's right eye to the second display device 10_2. In an alternative embodiment, the control circuit board 170 may transmit the same digital video data to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the display device housing (also referred to as a housing) 110. The housing cover 120 may include the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, the disclosure is not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

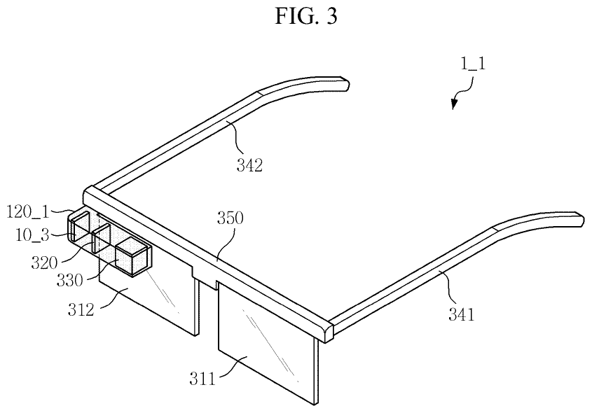

The head strap band 140 fixes the housing 110 to the user's head so that the first eyepiece 131 and the second eyepiece 132 of the housing cover 120 remain in line with the user's left and right eyes, respectively. By implementing a relatively light and small display device housing 110, the head-mounted electronic device 1 may include an eyeglasses frame as shown in FIG. 3 instead of a head strap band 140.

In addition, the head-mounted electronic device 1 may further include a battery for supplying power, an external memory slot for inserting an external memory, and an external connection port and a wireless communication module for receiving an image source. The external connection port may be a universal serial bus (“USB”) terminal, a display port, or a high-definition multimedia interface (“HDMI”) terminal. The wireless communication module may be a 5G communication module, a 4G communication module, a Wi-Fi module, or a Bluetooth™ module.

FIG. 3 is a perspective view showing an embodiment of a head-mounted electronic device according to the disclosure.

Referring to FIG. 3, the head-mounted electronic device 1_1 in the embodiment may be a glasses-type display device with a display device housing 120_1 which is relatively light and small. The head-mounted electronic device 1_1 in the embodiment may include a display device 10_3, a left-eye lens 311, a right-eye lens 312, a support frame 350, eyeglass temples 341 and 342, an optical member 320, an optical path conversion member 330, and a display device housing 120_1.

The display device 10_3 shown in FIG. 3 is substantially identical to the display device 10 described with reference to FIGS. 4 and 5. Therefore, descriptions of the first display device 10_1 and the second display device 10_2 will be replaced with descriptions referring to FIGS. 4 and 5.

The display device housing 120_1 may include the display device 10_3, the optical member 320, and the optical path conversion member 330. The images displayed on the display device 10_3 may be enlarged by the optical member 320, and the optical path of the images are converted by the optical path conversion member 330 to be provided to the user's right eye through the right eye lens 312. As a result, the user may see, with the right eye, augmented reality images that combine virtual images displayed on the display device 10_3 and real world images viewed through the right eye lens 312.

Although the display device housing 120_1 is disposed at the right end of the support frame 350 in the example shown in FIG. 3, the disclosure is not limited thereto. In an embodiment, the display device housing 120_1 may be disposed at the left end of the support frame 350, for example. In such case, images displayed on the display device 10_3 may be provided to the user's left eye. In an alternative embodiment, the display device housing 120_1 may be disposed at both the left and right ends of the support frame 350, respectively. In such case, the user may watch images displayed on the display device 10_3 through both the left and right eyes.

FIG. 4 is an exploded, perspective view showing an embodiment of a display device according to the disclosure.

Referring to FIG. 4, the display device 10 in the embodiment displays moving images or still images. The display device 10 in the embodiment may be employed by portable electronic devices such as a mobile phone, a smart phone, a tablet PC, a mobile communications terminal, an electronic notebook, an electronic book, a portable multimedia player (“PMP”), a navigation device and an ultra mobile PC (“UMPC”). In an embodiment, the display device 10 may be used as a display unit of a television, a laptop computer, a monitor, an electronic billboard, or the Internet of Things (“IoT”), for example. In an alternative embodiment, the display device 10 may be applied to a smart watch, a watch phone, or a head-mounted display (“HMD”) for implementing virtual reality and augmented reality.

According to the embodiment, the display device 10 includes a display panel 410, a heat dissipation layer 420, a circuit board 430, a driver circuit 440, and a power supply circuit 450.

The display panel 410 may have a shape similarly to a quadrangular shape, e.g., rectangular shape in a plan view. In an embodiment, the display panel 410 may have a shape similar to a rectangle having shorter sides in a first direction (x-axis direction) and longer sides in a second direction (y-axis direction) intersecting the first direction (x-axis direction) in a plan view. In the display panel 410, each of the corners where the shorter side in the first direction (x-axis direction) meets the longer side in the second direction (y-axis direction) may be rounded with a predetermined curvature or may be a right angle, for example. The shape of the display panel 410 in a plan view is not limited to a quadrangular shape, e.g., rectangular shape, but may be formed in a shape similar to other polygonal shapes, a circular shape, or an elliptical shape. The shape of the display device 10 may follow the shape of the display panel 410 in a plan view, but the disclosure is not limited thereto.

The display panel 410 includes a display area where images are displayed, and a non-display area where no image is displayed.

The display area includes a plurality of pixels, and each of the plurality of pixels includes a plurality of sub-pixels SP1, SP2 and SP3 (refer to FIG. 5). The sub-pixels SP1, SP2 and SP3 include a plurality of pixel transistors. The pixel transistors are formed via a semiconductor process and may be disposed on a semiconductor substrate SSUB (refer to FIG. 5). In an embodiment, the pixel transistors may be implemented as complementary metal oxide semiconductor (“CMOS”), for example.

The heat dissipation layer 420 may overlap with the display panel 410 in the third direction (z-axis direction), which is the thickness direction of the display panel 410. The heat dissipation layer 420 may be disposed on one surface of the display panel 410, e.g., on the rear surface. The heat dissipation layer 420 serves to release heat generated in the display panel 410. The heat dissipation layer 420 may include a metal layer such as graphite, silver (Ag), copper (Cu) and aluminum (Al) having a relatively high thermal conductivity.

The circuit board 430 may be electrically connected to a plurality of pads in a pad area of the display panel 410 using a conductive adhesive member such as an anisotropic conductive film. The circuit board 430 may be a flexible printed circuit board including or consisting of a flexible material, or a flexible film. Although the circuit board 430 is unfolded in FIG. 4, the circuit board 430 may be bent. When it is bent, one end of the circuit board 430 may be disposed on the rear surface of the display panel 410. The one end of the circuit board 430 may be opposite to the opposite end of the circuit board 430, which is connected to the pads in the pad area of the display panel 410 using a conductive adhesive member.

The driver circuit 440 may receive digital video data and timing signals from the outside. The driver circuit 440 may generate a scan timing control signal, an emission timing control signal, and a data timing control signal for controlling the display panel 410 in response to the timing signals.

A power supply circuit 450 may generate a plurality of panel driving voltages in response to a supply voltage from the outside.

Each of the driver circuit 440 and the power supply circuit 450 may be implemented as an integrated circuit (“IC”) and attached to a surface of the circuit board 430.

FIG. 5 is a cross-sectional view showing an embodiment of a part of a display panel according to the disclosure. FIG. 5 shows a cross-sectional structure of a part of a display area including a plurality of sub-pixels, for example.

Referring to FIG. 5, the display panel 410 includes a semiconductor backplane SBP, an emission material backplane EBP, an emission material layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed in the upper surface of the semiconductor substrate SSUB. The well areas WA may be doped with second-type impurities. The second-type impurities may be different from the first-type impurities. In an embodiment, when the first-type impurities are p-type impurities, the second-type impurities may be n-type impurities, for example. In an alternative embodiment, when the first-type impurities are n-type impurities, the second-type impurities may be p-type impurities.

The semiconductor substrate SSUB may be replaced with a glass substrate or a polymer resin substrate such as polyimide. In this instance, thin-film transistors may be disposed on a glass substrate or a polymer resin substrate. The glass substrate may be a rigid substrate that is not bent, while the polymer resin substrate may be a flexible substrate that may be bent or curved.

Each of the well areas WA includes a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. The gate electrode GE of the pixel transistor PTR may overlap with the well area WA in the third direction (z-axis direction). The channel region CH may overlap with the gate electrode GE in the third direction (z-axis direction). The source area SA may be disposed on one side of the gate electrode GE, and the drain area DA may be disposed on the opposite side of the gate electrode GE.

A first semiconductor insulating film SINS1 may be disposed on the semiconductor substrate SSUB. The first semiconductor insulating film SINS1 may include or consist of, but is not limited to, a silicon carbon nitride (SiCN) or a silicon oxide (SiOx)-based inorganic film.

A second semiconductor insulating film SINS2 may be disposed on the first semiconductor insulating film SINS1. The second semiconductor insulating film SINS2 may include or consist of a silicon oxide (SiOx)-based inorganic film, but the disclosure is not limited thereto.

A plurality of contact terminals CTE may be disposed on the second semiconductor insulating film SINS2. Each of the plurality of contact terminals CTE may be connected to one of the gate electrode GE, the source region SA and the drain region DA of each of the pixel transistors PTR through a hole penetrating the first semiconductor insulating film SINS1 and the second semiconductor insulating film SINS2. The contact terminals CTE may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of one of these.

A third semiconductor insulating film SINS3 may be disposed on the side surface of each of the contact terminals CTE. The upper surface of each of the contact terminals CTE may not be covered by the third semiconductor insulating film SINS3 but may be exposed. The third semiconductor insulating film SINS3 may include or consist of a silicon oxide (SiOx)-based inorganic film, but the disclosure is not limited thereto.

The emission material backplane EBP includes first to eighth metal layers ML1 to ML8, reflective metal layers RL1 to RL4, a plurality of vias VA1 to VA10, and a step layer STPL. In addition, the emission material backplane EBP includes a plurality of inter-dielectric films INS1 to INS10 disposed between the first to sixth metal layers ML1 to ML6.

The first to eighth metal layers ML1 to ML8 serve to implement a circuit of a sub-pixel SP by connecting a plurality of contact terminals CTE exposed from the semiconductor backplane SBP.

The first inter-dielectric film INS1 may be disposed on the semiconductor backplane SBP. Each of the first vias VA1 may penetrate the first inter-dielectric film INS1 and may be connected to the contact terminal CTE exposed from the semiconductor backplane SBP. Each of the first metal layers ML1 may be disposed on the first inter-dielectric film (also referred to as a first inter-insulating film) INS1 and may be connected to the first via VA1.

The second inter-dielectric film INS2 may be disposed on the first inter-dielectric film INS1 and the first metal layers ML1. Each of the second vias VA2 may penetrate through the second inter-dielectric film INS2 to be connected to the exposed first metal layer ML1. Each of the second metal layers ML2 may be disposed on the second inter-insulating film INS2 and may be connected to the second via VA2.

The third inter-dielectric film INS3 may be disposed on the second inter-dielectric film INS2 and the second metal layers ML2. Each of the third vias VA3 may penetrate through the third inter-dielectric film INS3 to be connected to the exposed second metal layer ML2. Each of the third metal layers ML3 may be disposed on the third inter-insulating film INS3 and may be connected to the third via VA3.

The fourth inter-dielectric film INS4 may be disposed on the third inter-dielectric film INS3 and the third metal layers ML3. Each of the fourth vias VA2 may penetrate through the fourth inter-dielectric film INS4 to be connected to the exposed third metal layer ML3. Each of the fourth metal layers ML4 may be disposed on the fourth inter-insulating film INS4 and may be connected to the fourth via VA4.

The fifth inter-dielectric film INS5 may be disposed on the fourth inter-dielectric film INS4 and the fourth metal layers ML4. Each of the fifth vias VA5 may penetrate through the fifth inter-dielectric film INS5 to be connected to the exposed fourth metal layer ML4. Each of the fifth metal layers ML5 may be disposed on the fifth inter-insulating film INS5 and may be connected to the fifth via VA5.

The sixth inter-dielectric film INS6 may be disposed on the fifth inter-dielectric film INS5 and the fifth metal layers ML5. Each of the sixth vias VA6 may penetrate through the sixth inter-dielectric film INS6 to be connected to the exposed fifth metal layer ML5. Each of the sixth metal layers ML6 may be disposed on the sixth inter-insulating film INS6 and may be connected to the sixth via VA6.

The seventh inter-dielectric film INS7 may be disposed on the sixth inter-dielectric film INS6 and the sixth metal layers ML6. Each of the seventh vias VA7 may penetrate through the seventh inter-dielectric film INS7 to be connected to the exposed sixth metal layer ML6. Each of the seventh metal layers ML7 may be disposed on the seventh inter-insulating film INS7 and may be connected to the seventh via VA7.

The eighth inter-dielectric film INS8 may be disposed on the seventh inter-dielectric film INS7 and the seventh metal layers ML7. Each of the eighth vias VA8 may penetrate through the eighth inter-dielectric film INS8 to be connected to the exposed seventh metal layer ML7. Each of the eighth metal layers ML8 may be disposed on the eighth inter-insulating film INS8 and may be connected to the eighth via VA8.

The first to eighth metal layers ML1 to ML8 and the first to eighth vias VA1 to VA8 may include or consist of substantially the same material as each other. The first to eighth metal layers ML1 to ML8 and the first to eighth vias VA1 to VA8 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these. The first to eighth vias VA1 to VA8 may include or consist of substantially the same material as each other. The first to eighth inter-dielectric films INS1 to INS8 may include or consist of a silicon oxide (SiOx)-based inorganic film, but embodiments of the specification are not limited thereto.

The thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6 may be greater than the thickness of the first via VA1, the thickness of the second via VA2, the thickness of the third via VA3, the thickness of the fourth via VA4, the thickness of the fifth via VA5 and the thickness of the sixth via VA6. The thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 may be substantially all equal.

The thickness of the seventh metal layer ML7 and the thickness of the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6. The thickness of the seventh metal layer ML7 and the thickness of the eighth metal layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5 and the thickness of the sixth via VA6. The thickness of the seventh metal layer ML7 may be substantially equal to the thickness of the eighth metal layer ML8.

The ninth inter-dielectric film INS9 may be disposed on the eighth inter-dielectric film INS8 and the eighth metal layers ML8. The ninth inter-dielectric film INS9 may include or consist of a silicon oxide (SiOx)-based inorganic film, but the disclosure is not limited thereto.

Each of the ninth vias VA9 may penetrate through the ninth inter-dielectric film INS9 to be connected to the exposed eighth metal layer ML8. The ninth vias VA9 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these.

The first reflective metal layers (also referred to as first reflective electrodes) RL1 may be disposed on the ninth inter-dielectric film INS9 and may be connected to the ninth via VA9. The first reflective electrodes RL1 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these.

The second reflective electrodes RL2 may be disposed on the first reflective electrodes RL1. The second reflective electrodes RL2 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these. In an embodiment, the second reflective electrodes RL2 may be titanium nitride (TiN), for example.

In the first sub-pixel SP1, a step layer STPL may be disposed on the second reflective electrode RL2. No step layer STPL may be disposed in each of the second sub-pixel SP2 and the third sub-pixel SP3. The thickness of the step layer STPL may be determined based on the wavelength of the light of a first color and the distance from a first emissive layer (EML corresponding to SP1) to a fourth reflective electrode RL4 so that the light of the first color emitted from the first emissive layer (EML corresponding to SP1) is advantageously reflected. The step layer STPL may include or consist of, but is not limited to, a silicon carbon nitride (SiCN) or a silicon oxide (SiOx)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these.

At least one of the first reflective electrode RL1, the second reflective electrode RL2 and the third reflective electrode RL3 may be eliminated.

The fourth reflective electrodes RL4 may be disposed on the third reflective electrodes RL3. The fourth reflective electrodes RL4 may reflect lights from the first emissive layer (EML corresponding to SP1), the second emissive layer (EML corresponding to SP2) and the third emissive layer (EML corresponding to SP3). The fourth reflective electrodes RL4 may include a metal with relatively high reflectivity to be advantageous for light reflection. The fourth reflective electrodes RL4 may be made up of, but is not limited to, aluminum (Al), a stack of aluminum and titanium (Ti/Al/Ti), a stack of aluminum and indium tin oxide (“ITO”) (ITO/Al/ITO), silver (Ag), palladium (Pd), and an aluminum polymer composite (“APC”) alloy, which is an alloy of copper (Cu), and a stack of an APC alloy and ITO (ITO/APC/ITO).

The tenth inter-dielectric film INS10 may be disposed on the ninth inter-dielectric film INS9 and the fourth reflective electrodes RL4. The tenth inter-dielectric film INS10 may include or consist of a silicon oxide (SiOx)-based inorganic film, but the disclosure is not limited thereto.

Each of the tenth vias VA10 may penetrate through the tenth inter-dielectric film INS10 to be connected to the exposed ninth metal layer ML9. The tenth vias VA10 may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LE each including a first electrode AND, an intermediate layer IL and a second electrode CAT, and a pixel-defining layer PDL.

The first electrode AND may be disposed on the tenth inter-dielectric film INS10 and may be connected to the tenth via VA10. The first electrode AND may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. The first electrode AND may include or consist of one of copper (Cu), aluminum (Al), tungsten (W), molybdenum (Mo), chromium (Cr), gold (Au), titanium (Ti), nickel (Ni) and neodymium (Nd), or an alloy including or consisting of at least one of these. In an embodiment, the first electrode AND may be titanium nitride (TiN), for example.

The pixel-defining layer PDL may be disposed partially on the first electrode AND. The pixel-defining layer PDL may be disposed on edges of the first electrode AND. The pixel-defining layer PDL serves to partition the first emission areas EA1, the second emission areas EA2 and the third emission areas EA3.

A first emission area EA1 may be defined as an area in the first sub-pixel SP1 where the first electrode AND, the intermediate layer IL and the second electrode CAT are sequentially stacked on one another to emit light. A second emission area EA2 may be defined as an area in the second sub-pixel SP2 where the first electrode AND, the intermediate layer IL and the second electrode CAT are sequentially stacked on one another to emit light. A third emission area EA3 may be defined as an area in the third sub-pixel SP3 where the first electrode AND, the intermediate layer IL and the second electrode CAT are sequentially stacked on one another to emit light.

The pixel-defining layer PDL may include first to third pixel-defining films PDL1, PDL2 and PDL3. The first pixel-defining film PDL1 may be disposed on the edge of the first electrode AND, the second pixel-defining film PDL2 may be disposed on the first pixel-defining film PDL1, and the third pixel-defining film PDL3 may be disposed on the second pixel-defining film PDL2. The first pixel-defining film PDL1, the second pixel-defining film PDL2 and the third pixel-defining film PDL3 may include or consist of a silicon oxide (SiOx)-based inorganic film, but the disclosure is not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2 and IL3 that emit different lights. In an embodiment, the intermediate layer IL may include the first intermediate layer IL1 that emits light of the first color, the second intermediate layer IL2 that emits light of the third color, and the third intermediate layer IL3 that emits light of the second color, for example. The first intermediate layer IL1, the second intermediate layer IL2 and the third intermediate layer IL3 may be sequentially stacked on one another.

The first intermediate layer IL1 may have a structure in which a first hole transport layer, a first organic emissive layer that emits light of the first color, and a first electron transport layer are sequentially stacked on one another. The second intermediate layer IL2 may have a structure in which a second hole transport layer, a second organic emissive layer that emits light of the third color, and a second electron transport layer are sequentially stacked on one another. The third intermediate layer IL3 may have a structure in which a third hole transport layer, a third organic emissive layer that emits light of the second color, and a third electron transport layer are sequentially stacked on one another.

A plurality of intermediate layers IL disposed adjacent to each other in the first direction (x-axis direction) may be disconnected by the pixel-defining layer PDL. In the display panel 410 in the embodiment, it is possible to prevent leakage current between adjacent sub-pixels SP1, SP2 and SP3 and to prevent color crosstalk by disconnecting the intermediate layers IL of the adjacent sub-pixels SP1, SP2 and SP3. The color crosstalk refers to, e.g., a phenomenon that a red sub-pixel adjacent to a blue sub-pixel is unintentionally turned on while the blue sub-pixel emits blue light. Since color crosstalk occurs due to leakage current, it may occur when a blue sub-pixel and a red sub-pixel are adjacent to each other, which have a relatively large difference in voltage for driving the sub-pixels. In an embodiment, while the driving current is supplied to the light-emitting element LE of a blue sub-pixel in order to turn on the blue sub-pixel, a part of the driving current may be transmitted to a red sub-pixel through at least some conductive layers of the intermediate layers IL, which is leakage current, for example. When leakage current is generated, the red sub-pixel may be unintentionally turned on while the blue sub-pixel is turned on.

The number of intermediate layers IL1, IL2 and IL3 emitting different lights is not limited to that shown in FIG. 5. In an embodiment, the intermediate layer IL may include two intermediate layers. In this instance, one of the two intermediate layers is substantially identical to the first intermediate layer IL1, and the other one of the two intermediate layers may include a second hole transport layer, a second organic emissive layer, a third organic emissive layer, and a second electron transport layer, for example. In this instance, a charge generation layer may be disposed between the two intermediate layers to supply electrons to one intermediate layer and to supply charges to the other intermediate layer.

Although the first to third intermediate layers IL1, IL2 and IL3 are all disposed in the first emission area EA1, the second emission area EA2 and the third emission area EA3 in FIG. 5, the disclosure is not limited thereto. In an embodiment, the first intermediate layer IL1 may be disposed in the first emission area EA1 but not in the second emission area EA2 and the third emission area EA3, for example. In addition, the second intermediate layer IL2 may be disposed in the second emission area EA2 but not in the first emission area EA1 and the third emission area EA3. In addition, the third intermediate layer IL3 may be disposed in the third emission area EA3 but not in the first emission area EA1 and the second emission area EA2. In this instance, the first to third color filters CF1, CF2 and CF3 of the optical layer OPL may be eliminated.

The second electrode CAT may be disposed on the third intermediate layer IL3. The second electrode CAT may include or consist of a transparent conductive material (“TCP”) such as ITO and indium zinc oxide (“IZO”) that may transmit light, or a semi-transmissive conductive material such as magnesium (Mg), silver (Ag) and an alloy of magnesium (Mg) and silver (Ag). When the second electrode CAT includes or consists of a semi-transmissive conductive material, the light extraction efficiency may be increased by microcavities in each of the first to third sub-pixels SP1, SP2 and SP3.

The encapsulation layer TFE may be disposed on the emission material layer EML. The encapsulation layer TFE may include one or more inorganic films TFE1 and TFE2 to prevent permeation of oxygen or moisture into the emission material layer EML. In addition, the encapsulation layer ENC may include at least one organic film to protect the emission material layer EML from particles such as dust. In an embodiment, the encapsulation layer ENC may include a first inorganic encapsulation film TFE1, an organic encapsulation film TFE2 and a second inorganic encapsulation film TFE3, for example.

The first inorganic encapsulation film TFE1 may be disposed on the second electrode CAT, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer (SiNx), a silicon oxynitride layer (SiON), a silicon oxide layer (SiOx), a titanium oxide layer (TiOx) and an aluminum oxide layer (AlOx) are alternately stacked on one another. The organic encapsulation film TFE2 may be a monomer. In an alternative embodiment, the organic encapsulation film TFE2 may be an organic film such as an acryl resin, an epoxy resin, a phenolic resin, a polyamide resin, a polyimide resin, etc.

An adhesive layer ADL may adhere the encapsulation layer TFE to the optical layer OPL. The adhesive layer ADL may be a double-sided adhesive member. In addition, the adhesive layer ADL may be a transparent adhesive member such as a transparent adhesive and a transparent adhesive resin.

The optical layer OPL includes a plurality of color filters CF1, CF2 and CF3, a plurality of lenses LNS, and a filling layer FIL. The plurality of color filters CF1, CF2 and CF3 may include first to third color filters CF1, CF2 and CF3. The first to third color filters CF1, CF2 and CF3 may be disposed on the adhesive layer ADL.

The first color filter CF1 may be in line with the first emission area EA1 of the first sub-pixel SP1. The first color filter CF1 may transmit light of the first color, i.e., light in the blue wavelength range. The blue wavelength range may be approximately 370 nanometers (nm) to approximately 460 nm. Therefore, the first color filter CF1 may transmit light of the first color among the lights emitted from the first emission area EA1.

The second color filter CF2 may be in line with the second emission area EA2 of the second sub-pixel SP2. The second color filter CF2 may transmit light of the second color, i.e., light in the green wavelength range. The green wavelength range may be approximately 480 nm to approximately 560 nm. Therefore, the second color filter CF2 may transmit light of the second color among the lights emitted from the second emission area EA2.

The third color filter CF3 may be in line with the third emission area EA3 of the third sub-pixel SP3. The third color filter CF3 may transmit light of the third color, i.e., light in the red wavelength range. The blue wavelength range may be approximately 600 nm to approximately 750 nm. Therefore, the third color filter CF3 may transmit light of the third color among the lights emitted from the third emission area EA3.

The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be disposed on a plurality of lenses LNS. The filling layer FIL may have a predetermined refractive index so that light travels in the third direction (z-axis direction) at the interface between the plurality of lenses LNS and the filling layer FIL. In addition, the filling layer FIL may be a planarization layer. The filling layer FIL may be an organic film such as an acryl resin, an epoxy resin, a phenolic resin, a polyamide resin, and a polyimide resin.

The cover layer CVL may be disposed on the filling layer FIL. The cover layer CVL may be a glass substrate or a polymer resin such as a resin. When the cover layer CVL is a glass substrate, it may be attached to the filling layer FIL. In this instance, the filling layer FIL may adhere the cover layer CVL. When the cover layer CVL is a glass substrate, it may work as an encapsulation substrate. When the cover layer CVL is a polymer resin such as a resin, it may be applied directly on the filling layer FIL.

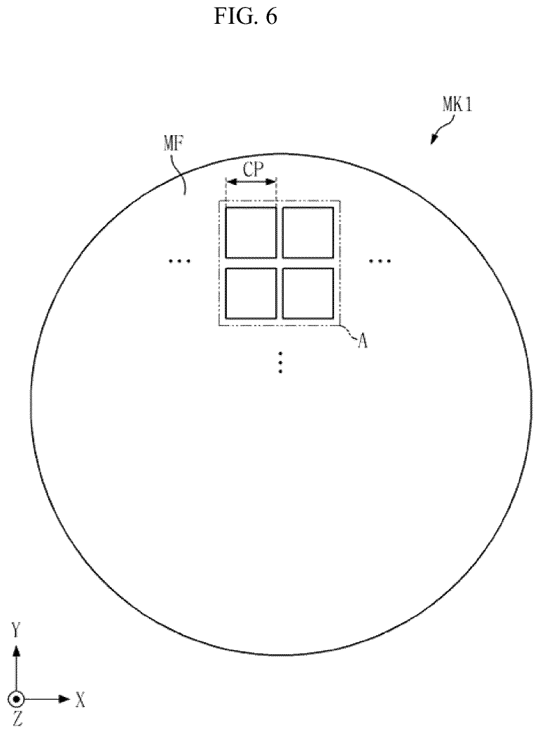

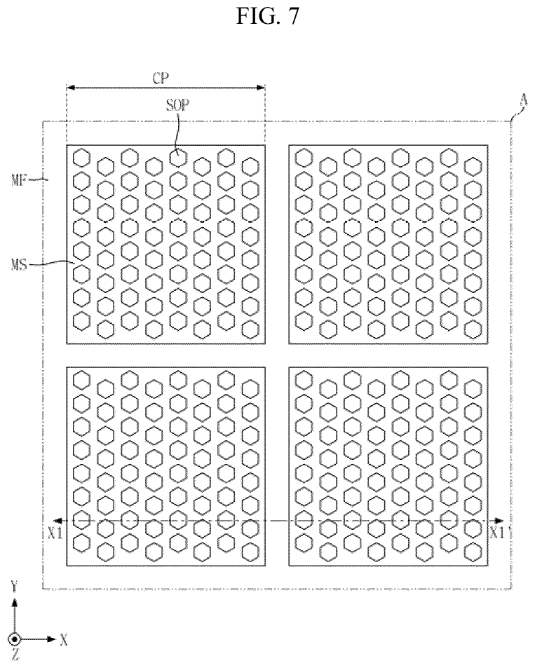

FIG. 6 is a plan view of an embodiment of a mask according to the disclosure. FIG. 7 is an enlarged plan view of area A of FIG. 6. The mask in the embodiment shown in FIG. 6 may be used in a process of depositing at least a part of the intermediate layer IL of the display panel 410 described above with reference to FIG. 5.

Referring to FIGS. 6 and 7, the mask MK1 in the embodiment may be a mask used to fabricate ultra-high resolution displays. In an embodiment, the mask MK1 may be a mask used to fabricate a display included in extended reality devices (XR devices) such as a virtual reality device (“VR device”), an augmented reality device (“AR device”) and a mixed reality device (“MR device”), for example.

The mask MK1 in the embodiment may be used to perform a deposition process of sub-pixels (the sub-pixels SP1, SP2 SP3 in FIG. 5) on a silicon wafer rather than a relatively large-area substrate used for existing displays. For a display included in an extended reality device, the screen is disposed directly in front of the user's eyes, and thus it may have a relatively small screen rather than a relatively large one. In addition, because it is disposed close to the user's eyes, ultra-high resolution may be desired. In an embodiment, the desired resolution of a display included in an extended reality device may be approximately 1,000 pixels per inch (PPI) or more, and preferably, an ultra-high resolution of approximately 2,000 PPI or more, for example. Accordingly, the deposition mask MK1 in the embodiment may be a mask used to fabricate such ultra-high resolution displays.

According to the embodiment of the disclosure, the mask MK1 may include a plurality of cell patterns CP and a mask frame MF.

The mask frame MF in the embodiment may be disposed to surround an entirety of the plurality of cell patterns CP in a plan view. The mask frame MF may support the mask MK1. The structure included in the mask frame MF will be described later in detail.

According to the embodiment of the disclosure, a plurality of cell patterns CP may be formed, and the cell patterns CP may be spaced apart from one another. According to the embodiment of the disclosure, the cell patterns CP may overlap with the plurality of pixels SP shown in FIG. 5. In the drawings, the cell patterns CP are shown in a quadrangular shape, e.g., rectangular shape, but the cell patterns CP are not limited thereto. In some implementations, the cell patterns CP may be formed in a variety of shapes such as a diamond, a pentagon, a circle and hexagon.

As shown in FIG. 7, the cell patterns CP may include mask shadows MS, and pixel openings SOP may be defined in the cell patterns CP. The mask shadows MS may surround the pixel openings SOP in a plan view, and the mask frame MF may surround the mask shadows MS in a plan view. The pixel openings SOP may be defined such that they overlap with the intermediate layer IL of the plurality of pixels SP shown in FIG. 5.

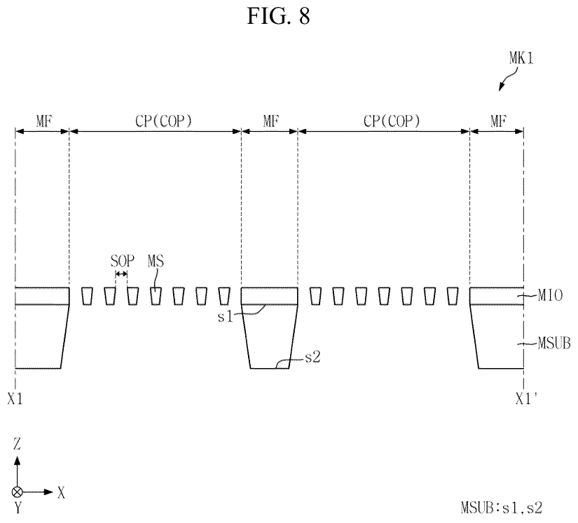

FIG. 8 is a cross-sectional view taken along line X1-X1′ of FIG. 7.

Referring to FIG. 8, a plurality of mask frames MF may be spaced apart from one another in the first direction (x-axis direction), and the plurality of mask frames MF spaced apart from one another may define the mask openings COP. The mask frames MF may include a mask substrate MSUB and a mask inorganic layer MIO.

The mask substrate MSUB may include a silicon wafer. Silicon wafers may be used as substrates for ultra-high resolution displays because they allow finer and more precise processing by utilizing the technologies developed in semiconductor processing than relatively large-area substrates. The mask MK1 in the embodiment may use a silicon wafer in the same manner to form pixels on the silicon wafer of such an ultra-high resolution display.

The shape of the mask substrate MSUB in the embodiment may conform to a silicon wafer of an ultra-high resolution display. In an embodiment, the mask substrate MSUB may have the same size or shape as the silicon wafer of the ultra-high resolution display, for example. It should be understood, however, that the disclosure is not limited thereto. The mask substrate MSUB may include a relatively large-area substrate. In an embodiment, the mask substrate MSUB may include a material such as glass, quartz and polymer resin, for example. When the mask substrate MSUB includes a relatively large-area substrate, the mask substrate MSUB may be formed in a quadrangular shape, e.g., rectangular shape as well as a circular shape.

According to the embodiment of the disclosure, the mask inorganic layer MIO may be disposed on the upper surface s1 of the mask substrate MSUB and may contact the upper surface s1. The mask inorganic layer MIO may include the same material as that of the mask shadows MS, which will be described later. The mask shadows MS and the mask inorganic layer MIO may be formed integrally during the fabrication process and then formed into the shape shown via a subsequent etching process.

The mask inorganic layer MIO may include an inorganic insulating material. In an embodiment, the mask inorganic layer MIO may include one of silicon nitride, silicon oxide, and silicon oxynitride, for example.

According to the embodiment, the cell patterns CP may be disposed in line with the mask openings COP. The plurality of cell patterns CP may be created by etching portions of the mask substrate MSUB from the lower surface s2 of the mask substrate MSUB.

According to the embodiment of the disclosure, the cell patterns CP may include a plurality of mask shadows MS. A plurality of neighboring mask shadows MS may define the pixel openings SOP. The plurality of pixel openings SOP may penetrate the mask frame MF along the thickness direction of the mask MK1 (e.g., third direction (z-axis direction)). The pixel openings SOP may be also referred to as holes or mask holes. The plurality of pixel openings SOP may be created by etching portions of the mask substrate MSUB from the lower surface s2 of the mask substrate MSUB.

The mask shadows MS may work as a blocking unit that masks a substrate subjected to deposition (e.g., the display panel 410, or backplane substrate) when a deposition material evaporates from a deposition source inside a deposition apparatus. Accordingly, the deposition material generated from the deposition source may be deposited on a surface of the substrate subjected to deposition (e.g., the display panel 410 or backplane substrate) through the pixel openings SOP.

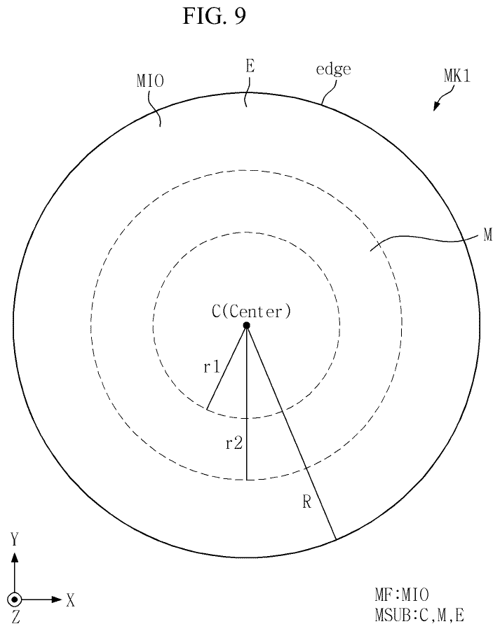

FIG. 9 is a plan view showing an embodiment of a layout of areas included in a mask substrate according to the disclosure.

Referring to FIG. 9, the mask substrate MSUB in the embodiment may include a center area C, an edge area E and a middle area M.

The center area C of the mask substrate MSUB may include a center point of the mask substrate MSUB and a peripheral area disposed close to the center point Center. The center area C of the mask substrate MSUB may be defined as a circle with a first radius rl from the center point. In an embodiment, the first radius r1 may range from 10% to 40% of the radius R of the mask substrate MSUB, for example. It should be understood, however, that the disclosure is not limited thereto.

The middle area M of the mask substrate MSUB may be defined as a circle with a second radius r2 from the center point excluding the center area C. In other words, the middle area M may surround the border of the center area C. In an embodiment, the second radius r2 may range from 30% to 70% of the radius R of the mask substrate MSUB, for example. It should be understood, however, that the disclosure is not limited thereto.

The edge area E of the mask substrate MSUB may include an edge of the mask substrate MSUB and a peripheral area disposed close to the edge. In other words, the edge area E may be defined as a circle with the radius R of the mask substrate MSUB from the center point, excluding the center area C and the middle area M. In other words, the edge area E may surround the border of the middle area M.

According to the embodiment of the disclosure, the mask substrate MSUB may have different degrees of warpage for different areas in a plan view. This may be because the mask inorganic layer MIO included in the mask frame MF has tensile stress or compressive stress.

In an embodiment, when the mask inorganic layer MIO is deposited on the entirety of the surface of the mask substrate MSUB in a plan view, the degree of warpage of the mask inorganic layer MIO on the edge area E of the mask substrate MSUB may be smaller than the degree of warpage of the mask inorganic layer MIO on the center area C of the mask substrate MSUB, for example. In other words, the degree of warpage of the mask inorganic layer MIO may decrease from the center point to the edge of the mask substrate MSUB.

In an embodiment, when cell patterns CP are formed where the mask inorganic layer MIO has a relatively high degree of warpage, the adhesion between the cell patterns CP of the mask MK1 and the display panel 410 shown in FIGS. 4 and 5 may decrease, resulting in deposition failure, for example.

Accordingly, in the mask MK1 in the embodiment, a plurality of cell patterns CP may be arranged differently depending on the degrees of warpage in different areas of the mask substrate MSUB.

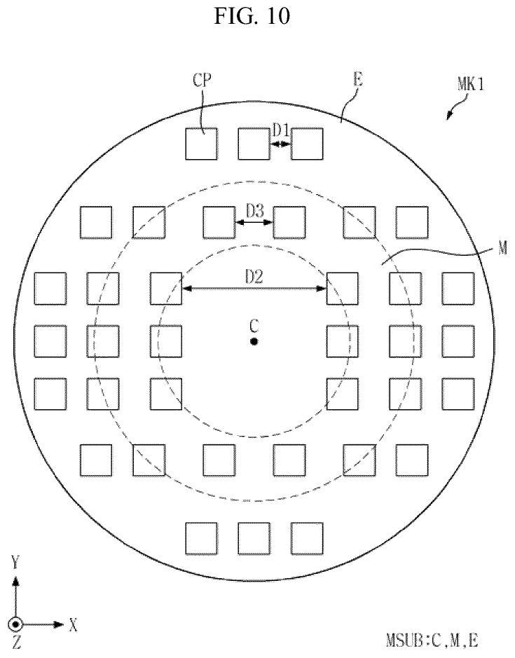

FIG. 10 is a plan view showing a plurality of cell patterns arranged on the mask substrate of FIG. 9.

Referring to FIG. 10, in the embodiment of the disclosure, the number of the cell patterns CP disposed on the edge area E may be greater than the number of the cell patterns CP disposed on the center area C. In other words, the number of cell patterns CP per unit area on the edge area E may be greater than the number of cell patterns CP per unit area on the center area C.

In addition, the number of cell patterns CP disposed on the middle area M may be greater than the number of cell patterns CP disposed on the center area C. In other words, the number of cell patterns CP per unit area on the edge area E may be greater than the number of cell patterns CP per unit area on the center area C.

In addition, the number of cell patterns CP disposed on the edge area E may be greater than the number of cell patterns CP disposed on the middle area M. It should be noted that the number of cell patterns CP disposed on the edge area E may be equal to the number of cell patterns CP disposed on the middle area M in some implementations.

That is to say, in the mask MK1 in the embodiment of the disclosure, the number of cell patterns CP disposed on the center area C may be smaller than the numbers of cell patterns CP disposed on the edge area E and the middle area M.

In some embodiments, a plurality of cell patterns CP may be spaced apart from one another by a first distance D1 on the edge area E. Herein, the cell patterns CP disposed across the edge area E and the middle area M may be regarded as being disposed on the edge area E. Therefore, the cell patterns CP disposed across the edge area E and the middle area M may be spaced apart from the cell patterns CP disposed only on the edge area E by the first distance D1.

In some embodiments, a plurality of cell patterns CP disposed on the center area C may be spaced apart from one another by a second distance D2. Herein, the cell patterns CP disposed across the center area C and the middle area M may be regarded as being disposed on the center area C. According to the embodiment, a plurality of cell patterns CP disposed on the middle area M may be spaced apart from one another by a third distance D3.

In some embodiments, the first distance D1, the second distance D2 and the third distance D3 may include different values from each other. Specifically, in the embodiment of the disclosure, the first distance D1 may be smaller than the second distance D2. That is to say, the plurality of cell patterns CP disposed on the edge area E may be spaced apart from one another by a smaller distance than the plurality of cell patterns CP disposed on the center area C. In other words, the plurality of cell patterns CP disposed on the edge area E may be arranged closer than the plurality of cell patterns CP disposed on the center area C.

In addition, the first distance D1 may be smaller than the third distance D3. That is to say, the plurality of cell patterns CP disposed on the edge area E may be spaced apart from one another by a smaller distance than the plurality of cell patterns CP disposed on the middle area M. In other words, the plurality of cell patterns CP disposed on the edge area E may be disposed closer than the plurality of cell patterns CP disposed on the middle area M and the center area C.

In addition, the third distance D3 may be smaller than the second distance D2. That is to say, the cell patterns CP disposed on the middle area M may be spaced apart from one another by a smaller distance than the cell patterns CP disposed on the center area C. In other words, the plurality of cell patterns CP disposed on the middle area M may be arranged closer than the plurality of cell patterns CP disposed on the center area C.

As described above, in the mask MK1 in the embodiment, more cell patterns CP are disposed on the edge area E where the degree of warpage is lowest than on the center area C where the degree of warpage is highest, so that the adhesion between the mask MK1 and the display panel 410 may be enhanced without warpage of the mask MK1.

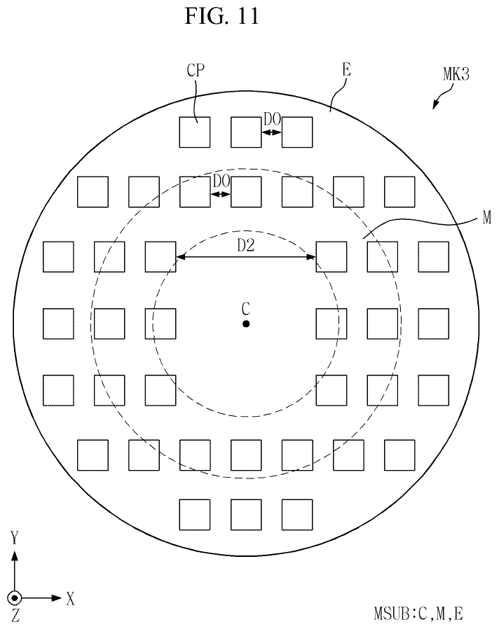

FIGS. 11 to 13 are plan views showing a plurality of cell patterns disposed on the mask substrate of FIG. 9 according to different embodiments.

A mask MK3 in an embodiment of FIG. 11 is similar to the mask MK1 in that cell patterns CP disposed on a center area C are spaced apart from one another by a second distance D2.

However, in the mask MK3 in the embodiment, a plurality of cell patterns CP disposed on the edge area E may be spaced apart from one another by a first distance D0, and a plurality of cell patterns CP disposed on the middle area M may also be spaced apart from one another by the first distance D0. In other words, the mask MK3 according to this embodiment is different from the mask MK1 in that the plurality of cell patterns CP may be spaced apart from one another by the same material distance on the edge area E as well as the middle area M.

In some embodiments, the second distance D2 may be greater than the first distance D0. That is to say, the cell patterns CP disposed on the edge area E and the middle area M may be spaced apart from one another by a smaller distance than the cell patterns CP disposed on the center area C. In other words, the cell patterns CP disposed on the edge area E and the middle area M may be arranged closer than the cell patterns CP disposed on the center area C. The redundant descriptions will be omitted.

In the mask MK3 in the embodiment, more cell patterns CP are disposed on the edge area E and the middle area M where the degree of warpage is lower than on the center area C where the degree of warpage is higher, so that the adhesion between the mask MK3 and the display panel 410 may be enhanced without warpage of the mask MK3.

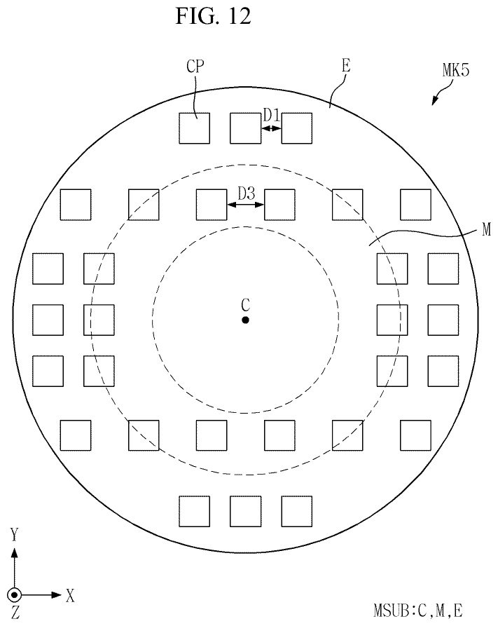

A mask MK5 in an embodiment of FIG. 12 is similar to the mask MK1 in that cell patterns CP disposed on an edge area E are spaced apart from one another by a first distance D1.

However, in the mask MK5 according to this embodiment, no cell pattern CP may be disposed on the center area C. The following description will focus on the difference between the mask MK1 and the mask MK5.

In the mask MK5 according to this embodiment, cell patterns CP disposed on the edge area E may be spaced apart from one another by the first distance D1, and cell patterns CP disposed on the middle area M may be spaced apart from one another by the third distance D3.

In some embodiments, the first distance D1 may be equal to or different from the third distance D3.

In an embodiment, when the first distance D1 is different from the third distance D3, the first distance D1 may be smaller than the third distance D3, for example. That is to say, the plurality of cell patterns CP disposed on the edge area E may be spaced apart from one another by a smaller distance than the plurality of cell patterns CP disposed on the middle area M. In other words, the plurality of cell patterns CP disposed on the edge area E may be arranged closer than the plurality of cell patterns CP disposed on the middle area M.

In an embodiment, when the first distance D1 is equal to the third distance D3, the mask MK5 in the embodiment may include a plurality of cell patterns CP spaced apart from one another by the same distance, for example.

In the mask MK5 in the embodiment, cell patterns CP are disposed on the middle area M and the edge area E where the degree of warpage is lower but not on the center area C where the degree of warpage is higher, so that the adhesion between the mask MK5 and the display panel 410 may be enhanced without warpage of the mask MK5.

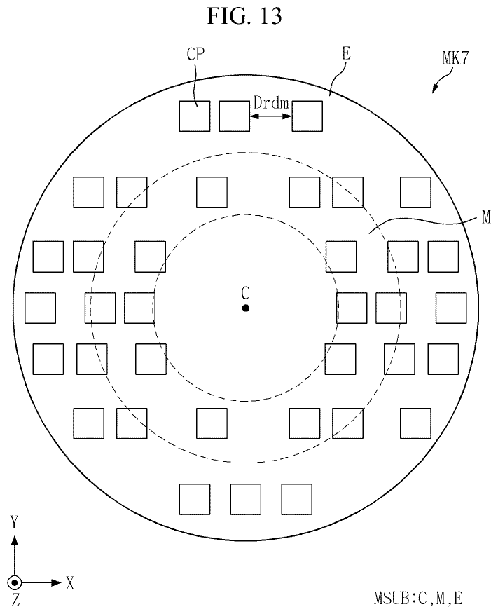

Referring to FIG. 13, the plurality of cell patterns CP included in a mask MK7 in an embodiment may be spaced apart from one another by random distances Drdm. In other words, the plurality of cell patterns CP included in the mask MK7 in the embodiment may be arranged irregularly by different distances. As used herein, the expression “irregularly” may have the same meaning as randomly.

According to the embodiment of the disclosure, the cell patterns CP may be arranged more densely on the edge area E than on the center area C. That is to say, the number of cell patterns CP per unit area on the edge area E and the middle area M may be greater than the number of cell patterns CP per unit area on the center area C.

According to this embodiment, the cell patterns CP disposed on the edge area E may be spaced apart from one another by different distances. In addition, according to this embodiment, a plurality of cell patterns CP disposed on the middle area M may also be spaced apart from one another by different distances. In addition, a plurality of cell patterns CP disposed on the center area C may be spaced apart from one another by different distances in the embodiment of the disclosure.

It should be noted that a plurality of cell patterns CP may not be disposed on the center area C in some implementations. When the cell patterns CP are not disposed on the center area C, a plurality of cell patterns CP may be formed densely on the edge area E and the middle area M, and a plurality of cell patterns CP on the edge area E and the middle area M may be arranged irregularly.

In the mask MK7 in the embodiment, more cell patterns CP are disposed on the edge area E where the degree of warpage is lower than on the center area C where the degree of warpage is higher, so that the adhesion between the mask MK7 and the display panel 410 may be enhanced without warpage of the mask MK7.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate comprising a center area and an edge area;
a plurality of cell patterns disposed on the mask substrate, the plurality of cell patterns including:
cell patterns disposed in the edge area; and
cell patterns disposed in the center area; and
a mask frame disposed on the mask substrate and surrounding the plurality of cell patterns,
wherein a number of cell patterns, among the cell patterns disposed in the edge area, per unit area of the edge area is greater than a number of cell patterns, among the cell patterns disposed in the center area, per unit area of the center area.

2. The deposition mask of claim 1, wherein the cell patterns on the edge area are spaced apart from one another by a first distance, and the cell patterns on the center area are spaced apart from one another by a second distance, wherein the first distance is different from the second distance.

3. The deposition mask of claim 2, wherein the second distance is greater than the first distance.

4. The deposition mask of claim 3, wherein the mask substrate further comprises a middle area disposed between the edge area and the center area,
wherein cell patterns on the middle area are spaced apart from one another by a third distance, and
wherein the first distance, the second distance and the third distance are different from one another.

5. The deposition mask of claim 4, wherein the third distance is smaller than the second distance.

6. The deposition mask of claim 4, wherein the third distance is greater than the first distance.

7. The deposition mask of claim 4, wherein the first distance is equal to the third distance.

8. The deposition mask of claim 1, wherein the center area comprises a center point of the mask substrate, and wherein the edge area comprises an edge of the mask substrate.

9. The deposition mask of claim 8, wherein the center area is in a shape of a circle having a first radius from the center point of the mask substrate, and wherein the first radius has a range of 10% to 40% relative to a radius of the mask substrate.

10. The deposition mask of claim 1, wherein the mask substrate comprises silicon, and wherein the mask substrate has a circular shape in a plan view.

11. The deposition mask of claim 1, wherein the cell patterns are disposed by random distances on the mask substrate.

12. The deposition mask of claim 1, wherein the mask frame comprises a mask inorganic layer disposed on the mask substrate, and
wherein the mask inorganic layer comprises an inorganic insulating material.

13. The deposition mask of claim 12, wherein a pixel opening is defined in a cell pattern of the plurality of cell patterns, and the cell pattern comprises a mask shadow surrounding the pixel opening.

14. The deposition mask of claim 13, wherein the mask shadow comprises a same material as a material of the mask inorganic layer.

15. The deposition mask of claim 14, wherein the pixel opening is a through hole, and wherein an ultra-high resolution pixel is formed through the pixel opening.

16. The deposition mask of claim 13, wherein the mask shadow surrounds an entirety of the pixel opening in a plan view, and wherein the mask frame surrounds an entirety of the mask shadow in the plan view.

17. A deposition mask comprising:
a mask substrate comprising a center area, an edge area and a middle area disposed between the center area and the edge area;
a plurality of cell patterns disposed on the mask substrate; and
a mask frame disposed on the mask substrate and surrounding the plurality of cell patterns,
wherein the plurality of cell patterns does not overlap with the center area, and the plurality of cell patterns is disposed on the edge area and the middle area.

18. The deposition mask of claim 17, wherein the cell patterns on the edge area are spaced apart from one another by a first distance, and the cell patterns on the middle area are spaced apart from one another by a second distance, wherein the first distance is different from the second distance.

19. The deposition mask of claim 17, wherein the cell patterns disposed on the edge area and the middle area are all spaced apart from one another by a first distance.

20. The deposition mask of claim 17, wherein the cell patterns are spaced apart from one another by random distances.
